(19) United States
(12) Patent Application Publication
(10) Pub. No.: US 2005/0042837 A1
(43) Pub. Date: Feb. 24, 2005

(54) Method of controlling depth of trench in shallow trench isolation and method of forming trench for isolation using the same

(76) Inventors: Jun-Sik Hong, Gyeonggi-do (KR); Jeong-Sic Jeon, Gyeonggi-do (KR); Tae Hyuk Ahn, Gyeonggi-do (KR); Dong-Hyun Kim, Gyeonggi-do (KR)

Correspondence Address: MARGER JOHNSON & MCCOLLOM PC, 1030 SW MORRISON STREET, PORTLAND, OR, 97205, US

(21) Appl. No.: 10/916,304

(22) Filed: Aug. 10, 2004

(30) Foreign Application Priority Data
Aug. 18, 2003 (KR) 2003-56848

(51) Int. Cl. H01L 21/76; H01L 21/311

(52) U.S. Cl. 438/424; 438/701

(57) ABSTRACT

According to some embodiments of the invention, a method of controlling the depth of a trench includes forming a mask layer on a semiconductor substrate, forming a sacrificial layer on the mask layer using a material having an etch selectivity ranging from a 1:1 to a 3:1 ratio with respect to the semiconductor substrate, forming a sacrificial pattern and a mask pattern by removing a portion of the sacrificial layer and a portion of the mask layer so that an isolation region of the semiconductor substrate is exposed, and forming a trench in the isolation region of the semiconductor substrate by performing a main etch process using a point at which the top surface of the mask pattern is exposed as an etch stop point so that the sacrificial pattern and the isolation region of the semiconductor substrate are simultaneously etched.

### CROSS REFERENCE TO RELATED APPLICATIONS

This application claims priority from Korean Patent Application No. 2003-56848, filed on Aug. 18, 2003, in the Korean Intellectual Property Office, the disclosure of which is incorporated by reference in its entirety for all purposes.

### BACKGROUND OF THE INVENTION

1. Field of the Invention

This disclosure relates in general to methods of fabricating semiconductor devices, and more particularly, to a method of controlling the depth of a trench in a semiconductor substrate during a shallow trench isolation (STI) process for forming an isolation region, and a method of forming a trench for isolation using the same.

2. Description of the Related Art

As the integration density of semiconductor devices increase, the size of patterns is being scaled down and the area of an active region where individual memory cells are formed is decreasing. In particular, the area of the active region for memory cells decreases due to a bird's beak that is caused by local oxidation of silicon (LOCOS). To increase the area of the active region, an STI process, in which a trench is formed in a substrate and filled with an isolation layer, is being widely used.

In a typical STI process, a mask pattern is formed on a semiconductor substrate such that an isolation region is exposed. Thereafter, the semiconductor substrate is etched using the mask pattern as an etch mask, thereby forming a trench. Conventionally, the trench is formed using a time etch process, which is carried out for a predetermined amount of time, to control the depth of the trench.

However, since the time etch process is affected by changes in the environment of equipment and a change in a dry etch rate, the depths of trenches formed in respective wafers are not uniform. In particular, because only one wafer is processed per etch process for forming a trench, a subsequently processed wafer is etched under different conditions from a previously processed wafer because of a time delay. Thus, a depth difference between a trench formed in the previous wafer and a trench formed in the subsequent wafer may become unacceptably large. Accordingly, uniform characteristics of wafers cannot be obtained by using the conventional method described above, and high reproducibility cannot be expected in mass production.

Embodiments of the invention address these and other disadvantages of the conventional art.

### SUMMARY OF THE INVENTION

The present invention provides a method of controlling the depth of a trench, to form trenches with a uniform depth in respective wafers using an STI process.

The present invention also provides a method of forming a trench for isolation, to form trenches using the foregoing method of controlling the depth of a trench so that trenches with a uniform depth can be formed in respective wafers using an STI process.

### BRIEF DESCRIPTION OF THE DRAWINGS

The above and other features and advantages of the invention will become more apparent by describing in detail exemplary embodiments thereof with reference to the attached drawings.

FIG. 1 is a flowchart illustrating a method of controlling the depth of a trench in an STI process according to some embodiments of the invention.

FIGS. 2 through 6 are cross-sectional diagrams illustrating a method of forming a trench for isolation according to some embodiments of the invention.

### DETAILED DESCRIPTION OF THE INVENTION

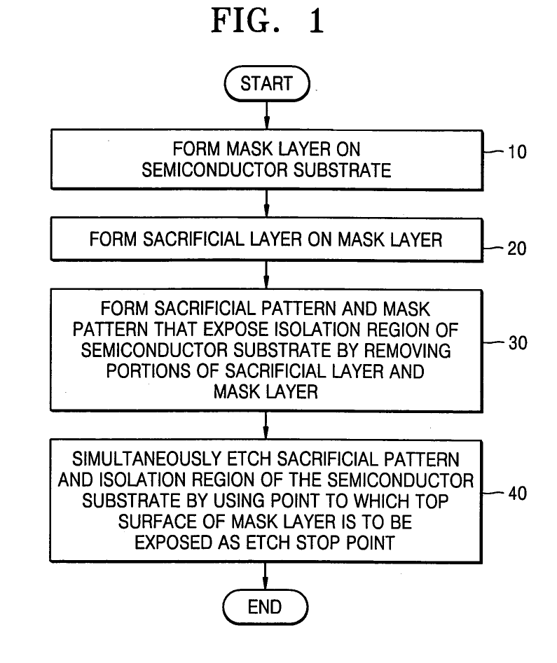

FIG. 1 is a flowchart illustrating a method of controlling the depth of a trench in an STI process according to some embodiments of the invention. Referring to FIG. 1, a mask layer is formed on a semiconductor substrate in process 10. The mask layer may be formed of, for example, a pad oxide layer and a silicon nitride layer.

In process 20, a sacrificial layer for controlling the depth of a trench (hereinafter, the sacrificial layer) is formed on the mask layer. The sacrificial layer is formed of a material having an etch selectivity of about 1:1 to 3:1 with respect to the semiconductor substrate, and depending on the depth of a trench to be formed, the thickness of the sacrificial layer is determined taking into account the etch selectivity of the sacrificial layer with respect to the semiconductor substrate.

The sacrificial layer may be formed of a Si-containing material. Preferably, the sacrificial layer is formed of polysilicon or SiON. If the sacrificial layer is formed of polysilicon, the etch selectivity of the sacrificial layer with respect to the semiconductor substrate formed of silicon is about 1:1, and the sacrificial layer is formed to a thickness that is almost the same as the depth of a trench to be formed. If the sacrificial layer is formed of SiON, the etch selectivity of the sacrificial layer with respect to the semiconductor substrate formed of silicon is about 3:1, and the sacrificial layer is formed to a thickness that is ⅓ the depth of a trench to be formed. For example, if a trench with a depth of about 1200 Å is to be formed in a main etch process, the SiON sacrificial layer is formed to a thickness of about 400 Å.

In process 30, the resultant structure is patterned using a photolithography process such that a portion of the sacrificial layer and a portion of the mask layer are removed. As a result, a sacrificial pattern for controlling the depth of a trench (hereinafter, a sacrificial pattern) and a mask pattern, which expose an isolation region of the semiconductor substrate, are formed.

In process 40, the sacrificial pattern and the isolation region of the semiconductor substrate are simultaneously etched using the main etch process, thereby forming a trench in the isolation region. Here, a point at which the top surface of the mask layer is exposed as a result of removing the sacrificial pattern using the etch process is deemed an etch stop point.

After the main etch process is finished, the isolation region of the semiconductor substrate may be over-etched using the mask pattern as an etch mask for a predetermined amount of time, thereby making the trench deeper.

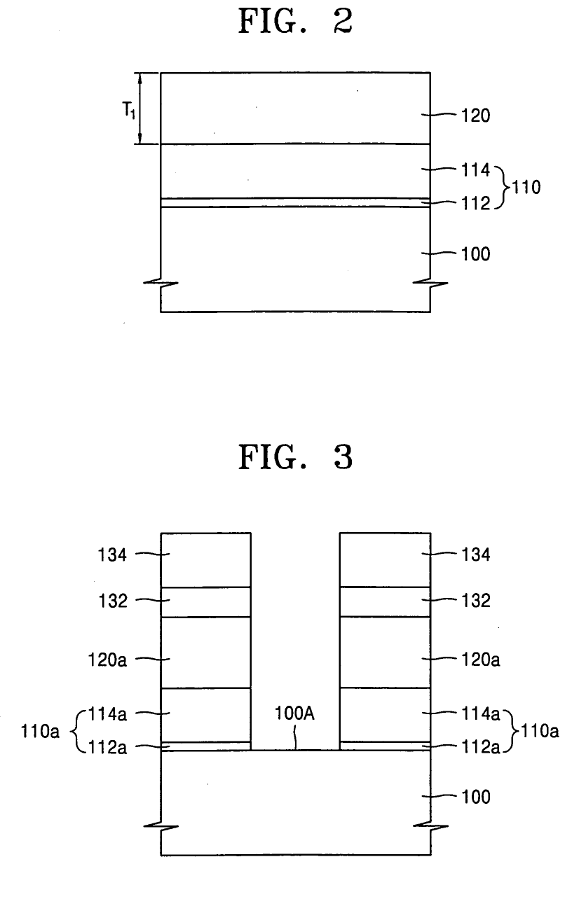

The foregoing method of controlling the depth of the trench in the STI process will be described below in more detail by the following method of forming a trench for isolation with reference to FIGS. 2 through 6.

FIGS. 2 through 6 are cross-sectional diagrams illustrating a method of forming a trench for isolation according to some embodiments of the invention.

Referring to FIG. 2, a mask layer 110 is formed on a silicon semiconductor substrate 100. To form the mask layer 110, a pad oxide layer 112 of about 100 Å and a silicon nitride layer 114 of about 1000 Å are sequentially formed on the semiconductor substrate 100.

Thereafter, a sacrificial layer 120 is formed on the mask layer 110. The sacrificial layer 120 is preferably formed of a Si-containing material having an etch selectivity of about 1:1 to 3:1 with respect to the silicon of the semiconductor substrate 100. More preferably, the sacrificial layer 120 is formed of polysilicon or SiON. The polysilicon is formed of either crystalline polysilicon or amorphous polysilicon. As described above, the thickness T₁ of the sacrificial layer 120 is determined by considering its etch selectivity with respect to the semiconductor substrate 100 and according to the depth of the trench to be formed. For example, if the sacrificial layer 120 is formed of polysilicon, the etch selectivity of the polysilicon with respect to the silicon of the semiconductor substrate 100 is about 1:1, and the thickness T₁ of the sacrificial layer 120 is formed to a thickness that is almost the same as the thickness of a trench to be formed. However, since the etch rate of the sacrificial layer 120 varies according to whether the polysilicon is crystalline polysilicon or amorphous polysilicon, checking for an accurate etch selectivity through simulations is required. Then, the thickness T₁ of the sacrificial layer 120 may be determined considering the etch selectivity and the depth of a trench to be formed.

According to the above-described embodiments, to form a trench to a depth of about 1500 Å using a main etch process, assuming that an etch selectivity of polysilicon with respect to silicon of the semiconductor substrate 100 is about 1:1, a polysilicon layer of about 1500 Å is formed as the sacrificial layer 120. However, the present invention is not limited to the embodiment. Although not shown in the drawings, if the sacrificial layer 120 is formed of SiON, the etch selectivity of the sacrificial layer 120 with respect to silicon of the semiconductor substrate 100 is about 3:1, and the sacrificial layer 120 is formed to a thickness of about 500 Å.

Referring to FIG. 3, an organic anti-reflective coating (ARC) layer (not shown) and a photoresist pattern 134 are sequentially formed on the sacrificial layer 120. The photoresist pattern 134 has a pattern shape that defines an active region of the semiconductor substrate 100. The organic ARC layer, the sacrificial layer 120, and the mask layer 110 are sequentially etched using the photoresist pattern 143 as an etch mask. As a result, an organic ARC pattern 132, a sacrificial pattern 120a, and a mask pattern 110a, which expose an isolation region 100A of the semiconductor substrate 100, are formed. The mask pattern 110a includes an oxide pattern 112a and a silicon nitride pattern 114a.

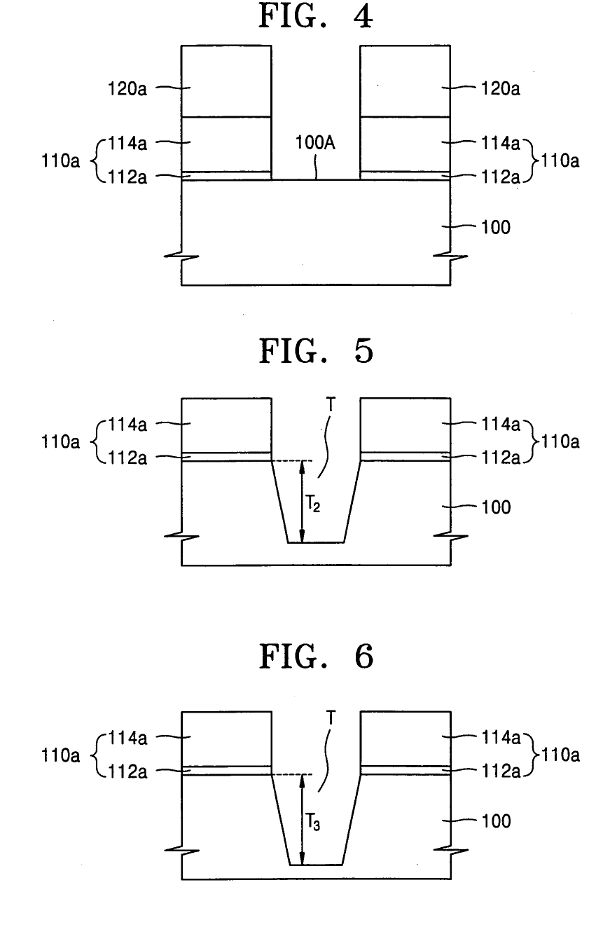

Referring to FIG. 4, the photoresist pattern 134 is removed by an ordinary ashing and stripping process. Here, the organic ARC pattern 132 is removed at the same time as the organic ARC pattern 132. As a result, the top surface of the sacrificial pattern 120a is exposed.

Referring to FIG. 5, a main etch process is performed so that the sacrificial layer 120a and the isolation region 100A of the semiconductor substrate 100 are simultaneously etched. The main etch process is performed using a mixture of Cl₂ gas and HBr gas as an etch gas. As a result of removing the sacrificial pattern 120a using the etch process, a point at which the top surface of the mask pattern 10a is exposed, i.e., a point at which the silicon nitride pattern 114a is exposed, is deemed an etch stop point.

In the main etch process, an end point detector (EPD) is used to precisely find the etch stop point. Since the EPD determines the point at which the silicon nitride pattern 114a is exposed as the etch stop point through an electrical output signal, the etch stop point can be precisely detected.

After the main etch process is stopped at the etch stop point that is determined through the signal of the EPD, since the sacrificial pattern 120a and the isolation region 100A of the semiconductor substrate 100 are simultaneously etched, the sacrificial pattern 120a is completely removed so that the top surface of the silicon nitride pattern 114a is exposed. Also, a trench T is formed in the isolation region 100A of the semiconductor substrate 100 such that the depth T₂ of the trench T is almost the same as the thickness T₁ of the sacrificial layer 120. Since the depth T₂ of the trench T is determined by the thickness T₁ of the sacrificial layer 120, even if there are changes in environment of equipment and changes in etch conditions caused by a time delay or the like, trenches T with a uniform depth T₂ can be formed in wafers.

Referring to FIG. 6, after the main etch process is carried out, the isolation region 110A of the semiconductor substrate 100 may be over-etched using the silicon nitride pattern 114a as an etch mask for a predetermined amount of time. Thus, a trench T may be formed to a depth T₃ that is larger than the depth T₂. The over-etch process can be performed using a mixture of, for example, Cl₂ gas and HBr gas.

As described above, the sacrificial pattern is formed on the mask pattern, and the main etch process for forming the trench in the isolation region is performed using the EPD, which detects the point at which the top surface of the mask pattern is exposed as the etch stop point. Since the EPD determines the point at which the mask pattern is exposed as the etch stop point through the electrical output signal, the etch stop point can be precisely detected. Accordingly, in the STI process, trenches with a uniform depth can be formed in wafers without incurring problems such as voids, dents, or the like.

The invention may be practiced in many ways. What follows are exemplary, non-limiting descriptions of some embodiments of the invention.

A method of controlling the depth of a trench in a shallow trench isolation process is provided by some embodiments of the invention. In this method, a mask layer is formed on a semiconductor substrate. A sacrificial layer is formed on the mask layer using a material having an etch selectivity ranging from a 1:1 to a 3:1 ratio with respect to the semiconductor substrate. A sacrificial pattern and a mask pattern are formed by removing a portion of the sacrificial layer and a portion of the mask layer so that an isolation region of the semiconductor substrate is exposed. A trench is formed in the isolation region of the semiconductor substrate by performing a main etch process using a point at which the top surface of the mask pattern is exposed as an etch stop point so that the sacrificial pattern and the isolation region of the semiconductor substrate are simultaneously etched.

A method of forming a trench for isolation is provided by other embodiments of the invention. In this method, a pad oxide layer is formed on a semiconductor substrate, and a silicon nitride layer is formed on the pad oxide layer. A sacrificial layer is formed on the silicon nitride layer using a material having an etch selectivity ranging from a 1:1 to a 3:1 ratio with respect to the semiconductor substrate. The sacrificial layer, the silicon nitride layer, and the pad oxide layer are patterned using a photolithography process such that a pad oxide pattern, a silicon nitride pattern, and a sacrificial pattern, which expose an isolation region of the semiconductor substrate, are formed. A main etch process is performed using a point at which the top surface of the silicon nitride pattern is exposed as an etch stop point, so that the sacrificial pattern and the isolation region of the semiconductor substrate are simultaneously etched.

The sacrificial layer may be formed of a Si-containing material. The sacrificial layer may be formed of either polysilicon or SiON.

The method may further include forming an organic anti-reflective coating layer on the sacrificial layer. In this case, the sacrificial layer, the silicon nitride layer, and the pad oxide layer may be patterned using a photoresist pattern formed on the organic anti-reflective coating layer as an etch mask.

After performing the main etch process, the method may further include over-etching the isolation region of the semiconductor substrate using the silicon nitride layer as an etch mask. The isolation region of the semiconductor substrate may be over-etched for a predetermined amount of time.

According to embodiments of the invention, a sacrificial pattern for controlling the depth of a trench is formed on a mask pattern, and a main etch process for forming the trench is performed using a point at which the top surface of the mask pattern is exposed as the etch stop point. Thus, in an STI process, trenches with a uniform depth can be formed in wafers.

While the invention has been particularly shown and described with reference to exemplary embodiments thereof, it will be understood by those of ordinary skill in the art that various changes in form and details may be made therein without departing from the spirit and scope of the present invention as defined by the following claims.

1. A method of controlling the depth of a trench in a shallow trench isolation process, the method comprising:
forming a mask layer on a semiconductor substrate;
forming a sacrificial layer on the mask layer using a material having an etch selectivity with respect to the semiconductor substrate ranging from a 1:1 to a 3:1 ratio;
forming a sacrificial pattern and a mask pattern by removing a portion of the sacrificial layer and a portion of the mask layer, respectively, to form a sacrificial pattern and a mask pattern that expose an isolation region of the semiconductor substrate; and
etching using a point at which the top surface of the mask pattern is exposed as an etch stop point so that the sacrificial pattern and the isolation region of the semiconductor substrate are simultaneously etched to form a trench in the isolation region of the semiconductor substrate.

2. The method of claim 1, wherein forming the mask layer comprises:
forming a pad oxide layer; and
forming a silicon nitride layer on the pad oxide layer.

3. The method of claim 1, wherein forming the sacrificial layer comprises forming the sacrificial layer of a Si-containing material.

4. The method of claim 3, wherein forming the sacrificial layer further comprises forming the sacrificial layer of polysilicon or SiON.

5. The method of claim 1, wherein forming the sacrificial pattern and the mask pattern comprises etching the sacrificial layer and the mask layer using a photoresist pattern formed on the sacrificial layer as an etch mask.

6. The method of claim 1, wherein forming the sacrificial pattern and the mask pattern comprises:
forming an organic anti-reflective coating layer on the sacrificial layer; and
etching the organic anti-reflective coating layer, the sacrificial layer, and the mask layer using a photoresist pattern formed on the organic anti-reflective coating layer as an etch mask.

7. The method of claim 1, further comprising, after etching, over-etching the isolation region of the semiconductor substrate for a predetermined amount of time using the mask pattern as an etch mask.

8. A method of forming a trench for isolation, the method comprising:
forming a pad oxide layer on a semiconductor substrate;
forming a silicon nitride layer on the pad oxide layer;
forming a sacrificial layer on the silicon nitride layer using a material having an etch selectivity ranging from a 1:1 to a 3:1 ratio with respect to the semiconductor substrate;
patterning the sacrificial layer, the silicon nitride layer, and the pad oxide layer using a photolithography process such that a pad oxide pattern, a silicon nitride pattern, and a sacrificial pattern, which expose an isolation region of the semiconductor substrate, are formed; and
performing a main etch process using a point at which the top surface of the silicon nitride pattern is exposed as an etch stop point, so that the sacrificial pattern and the isolation region of the semiconductor substrate are simultaneously etched.

9. The method of claim 8, wherein the sacrificial layer is formed of a Si-containing material.

10. The method of claim 9, wherein the sacrificial layer is formed of one of polysilicon and SiON.

11. The method of claim 8, wherein the main etch process is performed using a mixture of Cl₂ gas and HBr gas as an etch gas.

12. The method of claim 8, further comprising forming an organic anti-reflective coating layer on the sacrificial layer,
wherein the patterning of the sacrificial layer, the silicon nitride layer, and the pad oxide layer is performed using a photoresist pattern formed on the organic anti-reflective coating layer as an etch mask.

13. The method of claim 8, after performing the main etch process, further comprising over-etching the isolation region of the semiconductor substrate using the silicon nitride layer as an etch mask.

14. The method of claim 13, wherein the over-etching of the isolation region of the semiconductor substrate is performed for a predetermined amount of time.

15. The method of claim 13, wherein the over-etching of the isolation region of the semiconductor substrate is performed using a mixture of Cl₂ gas and HBr gas as an etch gas.

16. A method comprising:
depositing a pad oxide layer on a semiconductor substrate;
depositing a silicon nitride layer on the pad oxide layer;
depositing a sacrificial layer on the silicon nitride layer, the sacrificial layer having an etch selectivity with respect to the semiconductor substrate ranging from a 1:1 to a 3:1 ratio;
patterning the sacrificial layer, the silicon nitride layer, and the pad oxide layer using a photolithography process to form a pad oxide pattern, a silicon nitride pattern, and a sacrificial pattern, respectively, which expose an isolation region of the semiconductor substrate; and
simultaneously etching the sacrificial pattern and the isolation region by using a point at which the top surface of the silicon nitride pattern is exposed as an etch stop point.

17. The method of claim 16, wherein depositing the sacrificial layer comprises depositing a Si-containing material.

18. The method of claim 17, wherein depositing a Si-containing material comprises depositing polysilicon or SiON.

19. The method of claim 16, wherein simultaneously etching comprises etching with an etch gas mixture consisting of Cl₂ gas and HBr gas.

20. The method of claim 16, further comprising:
depositing an organic anti-reflective coating layer on the sacrificial layer;
depositing a photoresist pattern on the organic anti-reflective coating layer; and
using the photoresist pattern as an etch mask when patterning the sacrificial layer, the silicon nitride layer, and the pad oxide layer.

21. The method of claim 16, further comprising, after simultaneously etching the sacrificial pattern and the isolation region:
over-etching the isolation region using the silicon nitride layer as an etch mask.

22. The method of claim 21, wherein over-etching the isolation region comprises over-etching for a predetermined amount of time.

23. The method of claim 21, wherein over-etching the isolation region comprises over-etching using an etch gas mixture consisting of Cl₂ gas and HBr gas.
